(19) United States
(12) Patent Application Publication
(10) Pub. No.: US 2022/0232744 A1
(43) Pub. Date: Jul. 21, 2022

(54) Wearable Signal Blocking Device

(71) Applicants: Graham Dugoni, San Francisco, CA (US); Natalie Serle, San Francisco, CA (US); Karl Fritzsche, Bainbridge Island, WA (US); Blake Maurer, Renton, CA (US); Katie Lee, Portland, OR (US); Dan Nicholson, Portland, OR (US); Benjamin Weatherhead, Portland, ME (US); Wesley Hare, Portland, OR (US); Paul Backett, Portland, OR (US)

(72) Inventors: Graham Dugoni, San Francisco, CA (US); Natalie Serle, San Francisco, CA (US); Karl Fritzsche, Bainbridge Island, WA (US); Blake Maurer, Renton, CA (US); Katie Lee, Portland, OR (US); Dan Nicholson, Portland, OR (US); Benjamin Weatherhead, Portland, ME (US); Wesley Hare, Portland, OR (US); Paul Backett, Portland, OR (US)

(21) Appl. No.: 17/151,315

(22) Filed: Jan. 18, 2021

(51) Int. Cl. H05K 9/00

(52) U.S. Cl. CPC H05K 9/0081

(57) ABSTRACT

A wearable signal blocking device and method is provided. The wearable signal blocking device comprises a flexible sheet configured to be worn by a user and a panel defining a cavity for receiving an electronic device and at least partially obscuring a signal therefrom. The wearable signal blocking method comprises the steps of providing a flexible sheet having a panel disposed diagonally to a first corner between a first side and a second side thereof; inserting the electronic device into the cavity; rolling the panel and the first corner once or more toward a third corner of the flexible sheet; folding a second corner and a fourth corner of the flexible sheet inward toward the panel; and rolling the panel once or more into the third corner. The wearable signal blocking method alternatively comprises the steps of providing a flexible sheet having a panel disposed along a first corner between a first side and a second side thereof; inserting the electronic device into the cavity; rolling the first side and the panel once or more toward a third side of the flexible sheet; and rolling the second side and the panel once or more toward a fourth side of the flexible sheet.

### GOVERNMENT CONTRACT

Not applicable.

### CROSS-REFERENCE TO RELATED APPLICATIONS

Not applicable.

### STATEMENT RE. FEDERALLY SPONSORED RESEARCH/DEVELOPMENT

Not applicable.

### COPYRIGHT & TRADEMARK NOTICES

A portion of the disclosure of this patent document may contain material which is subject to copyright protection. This patent document may show and/or describe matter which is or may become trade dress of the owner. The copyright and trade dress owner has no objection to the facsimile reproduction by any one of the patent document or the patent disclosure, as it appears in the Patent and Trademark Office patent files or records, but otherwise reserves all copyrights and trade dress rights whatsoever.

### TECHNICAL FIELD

The disclosed subject matter relates generally to wearable signal blocking devices and methods and, more particularly, to a wearable signal blocking device featuring a flexible sheet having a panel defined by a cavity for receiving an electronic device and at least partially obscuring a signal therefrom.

### BACKGROUND

The advent and ubiquity of mobile and other electronic devices has introduced unwanted consequences. Indeed, electronic devices conveniently enhance wireless communication and connectivity in most settings. The availability of such services via these devices has led many individuals to constantly or frequently utilize these devices in most contexts. However, the pervasive use of such devices has proven unwelcome in certain settings, such as live events or performances. Generally, when users are constantly using their electronic devices, such users become less present and instead, experience the world via their device.

Basic attempts have been made to mitigate these undesirable consequences of connectivity. For instance, venues may post signs or rules against using devices. Such attempts have often proven unsuccessful because it remains difficult to enforce these standards against a large group of individuals. In addition, users will inevitably attempt to sneak a peek at their devices as it is difficult to avoid the temptation when the device is within reach.

As a result, despite various attempts to solve the problem of the pervasive use of electronic devices, none of those in existence combine the characteristics of the present invention. Thus, there remains a need for a wearable signal blocking device and method.

### SUMMARY

The present disclosure is directed to devices and methods for limiting access to or use of personal electronic devices, such as smartphones. In some instances, the disclosed device and method may be utilized within certain geographic locations or during certain periods of time. For example, the disclosed device and method may be useful during a live event, such as a concert, play, or other performance in which use of mobile devices negatively affects users' enjoyment or experience of said performance. The disclosed device and method may also prove useful for retaining the user's electronic device while driving, during private conversations, or other scenarios.

For purposes of summarizing, certain aspects, advantages, and novel features have been described. It is to be understood that not all such advantages may be achieved in accordance with any one particular embodiment. Thus, the disclosed subject matter may be embodied or carried out in a manner that achieves or optimizes one advantage or group of advantages without achieving all advantages as may be taught or suggested.

In accordance with one embodiment, the wearable signal blocking device may comprise a flexible sheet and a panel. In such embodiments, the flexible sheet may be configured to be worn by a user and may have a first side, a second side, a third side, and a fourth side. Moreover, the flexible sheet may be formed out of fabric or any other convenient material. The flexible sheet may further comprise a first corner disposed between the first side and the second side, a second corner disposed between the second side and the third side, a third corner disposed between the third side and the fourth side, and a fourth corner disposed between the fourth side and the first side. In some embodiments, the panel may be disposed along the entire surface area of the flexible sheet or along one or more portions thereof.

In other embodiments, the panel may be disposed along one of the first corner, the second corner, the third corner, or the fourth corner of the flexible sheet. Configured in this manner, the panel may define a cavity for receiving an electronic device, such as a mobile electronic device. The panel may further at least partially obscure a signal from the electronic device. In some embodiments, the panel may at least partially, or fully, obscure the signal from the electronic device until a predetermined condition is met. The predetermined condition may relate to a geographic location or a time period. For instance, the predetermined condition may be a concert or performance venue. As another example, the predetermined condition may be a performance or live event duration.

The panel may further comprise a locking means. The locking means may at least partially secure the cavity and therefore, may render the electronic device inaccessible to the user. According to certain embodiments, the locking means may comprise a foldable flap. In other embodiments, the panel may be foldable within the flexible sheet so as to form a burrito fold or a square fold.

In one embodiment of the present invention, a method involving the aforementioned wearable signal blocking device may be used to conveniently fold and store the electronic device, such as during the predetermined condition. The method may comprise the steps of: providing a flexible sheet having a panel disposed diagonally to a first corner between a first side and a second side of the flexible sheet, wherein the panel defines a cavity for receiving an electronic device and at least partially obscuring a signal therefrom; inserting the electronic device into the cavity; rolling the panel and the first corner once or more toward a third corner of the flexible sheet; folding a second corner and a fourth corner of the flexible sheet inward toward the panel; and rolling the panel once or more into the third corner.

In accordance with alternative embodiments, the method may comprise the steps of: providing a flexible sheet having a panel disposed along a first corner between a first side and a second side of the flexible sheet, wherein the panel defines a cavity for receiving an electronic device and at least partially obscuring a signal therefrom; inserting the electronic device into the cavity; rolling the first side and the panel once or more toward a third side of the flexible sheet; and rolling the second side and the panel once or more toward a fourth side of the flexible sheet.

One or more of the above-disclosed embodiments, in addition to certain alternatives, are provided in further detail below with reference to the attached figures. The disclosed subject matter is not, however, limited to any particular embodiment disclosed.

### BRIEF DESCRIPTION OF THE DRAWINGS

FIG. 1A shows a top down view of an embodiment of the wearable signal blocking device and method.

FIG. 1B shows a top down view of an embodiment of the wearable signal blocking device and method.

FIG. 1C shows a top down view of an embodiment of the wearable signal blocking device and method.

FIG. 1D shows a top down view of an embodiment of the wearable signal blocking device and method.

FIG. 2A shows a top down view of an embodiment of the wearable signal blocking device and method.

FIG. 2B shows a top down view of an embodiment of the wearable signal blocking device and method.

FIG. 2C shows a top down view of an embodiment of the wearable signal blocking device and method.

FIG. 2D shows a top down view of an embodiment of the wearable signal blocking device and method.

FIG. 3A shows a perspective view of an embodiment of the wearable signal blocking device and method.

FIG. 3B shows a perspective view of an embodiment of the wearable signal blocking device and method.

FIG. 3C shows a perspective view of an embodiment of the wearable signal blocking device and method.

FIG. 4 shows an embodiment of the wearable signal blocking method.

FIG. 5 shows an embodiment of the wearable signal blocking method.

The disclosed embodiments may be better understood by referring to the figures in the attached drawings, as provided below. The attached figures are provided as non-limiting examples for providing an enabling description of the method and system claimed. Attention is called to the fact, however, that the appended drawings illustrate only typical embodiments of this invention and are therefore not to be considered as limiting of its scope. One skilled in the art will understand that the invention may be practiced without some of the details included in order to provide a thorough enabling description of such embodiments. Well-known structures and functions have not been shown or described in detail to avoid unnecessarily obscuring the description of the embodiments.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus

The terms “couple,” “coupled,” “couples,” “coupling,” and the like should be broadly understood and refer to connecting two or more elements or signals, electrically, mechanically or otherwise. Two or more electrical elements may be electrically coupled, but not mechanically or otherwise coupled; two or more mechanical elements may be mechanically coupled, but not electrically or otherwise coupled; two or more electrical elements may be mechanically coupled, but not electrically or otherwise coupled. Coupling (whether mechanical, electrical, or otherwise) may be for any length of time, e.g., permanent or semi-permanent or only for an instant.

### DETAILED DESCRIPTION

Having summarized various aspects of the present disclosure, reference will now be made in detail to that which is illustrated in the drawings. While the disclosure will be described in connection with these drawings, there is no intent to limit it to the embodiment or embodiments disclosed herein. Rather, the intent is to cover all alternatives, modifications and equivalents included within the spirit and scope of the disclosure as defined by the appended claims.

With reference to the FIGS., the wearable signal blocking device 100 may comprise a flexible sheet 110 and a panel 120. The flexible sheet 110 may be configured to be worn by a user. As such, the flexible sheet 110 may be formed out of any convenient fabric, such as cotton, or other material. The flexible sheet 110 may comprise a first side 112, a second side 114, a third side 116, and a fourth side 118. In such embodiments, the flexible sheet 110 may be configured as a quadrilateral. In alternate embodiments, the flexible sheet 110 may comprise more or less sides. In further embodiments (not shown), the flexible sheet 110 may be generally formed as a circle and therefore, may comprise one continuous side.

As shown in the FIGS., in embodiments where the flexible sheet 110 may be configured as a quadrilateral having the first side 112, the second side 114, the third side 116, and the fourth side 118, the flexible sheet may further comprise a first corner 113 disposed between the first side 112 and the second side 114, a second corner 115 disposed between the second side 114 and the third side 116, a third corner 117 disposed between the third side 116 and the fourth side 118, and a fourth corner 119 disposed between the fourth side 118 and the first side 112.

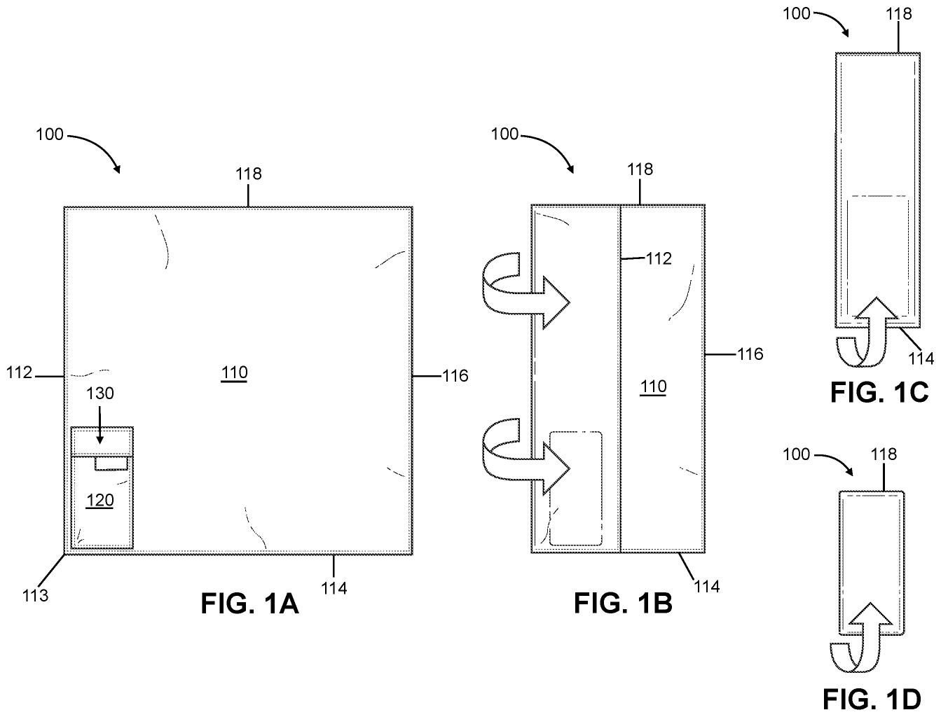

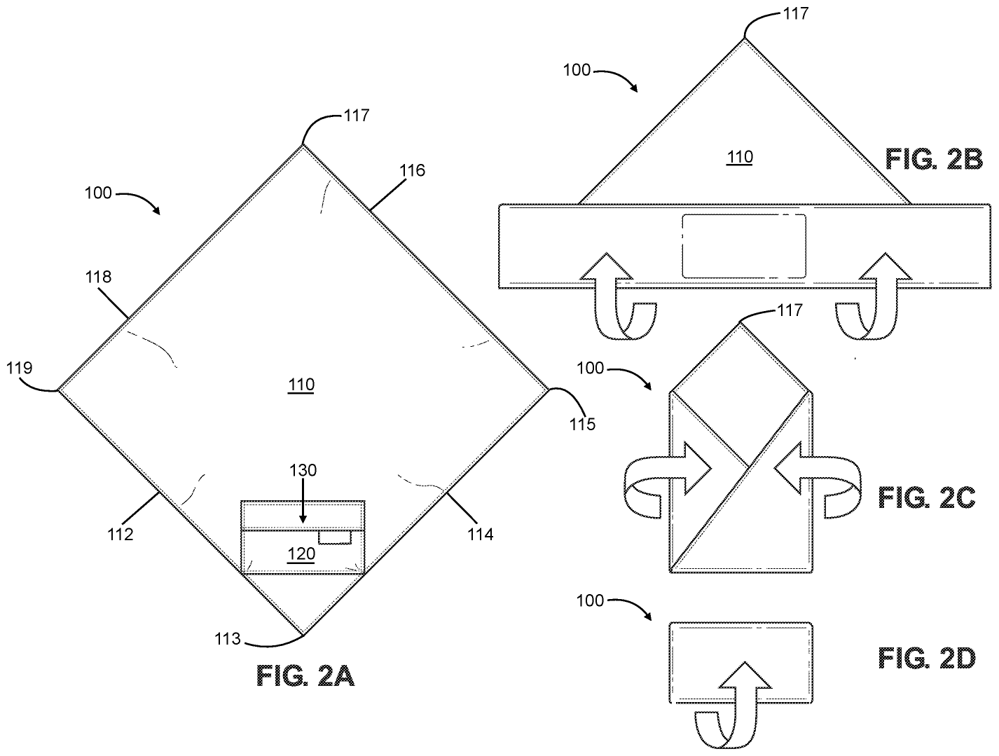

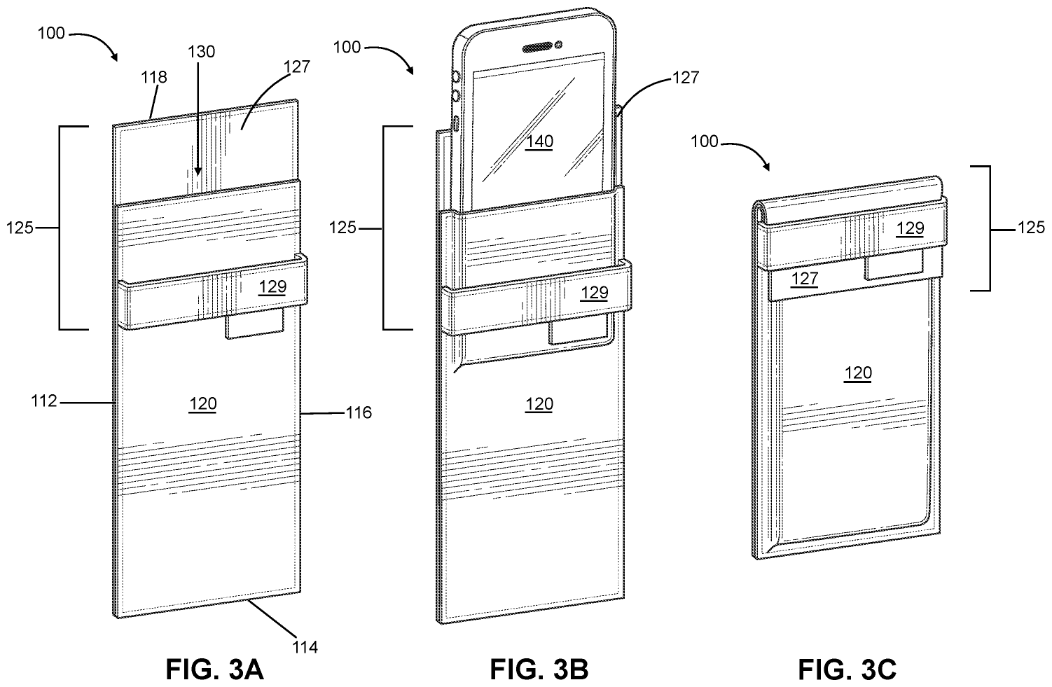

The panel 120 may be disposed anywhere along the flexible sheet 110. In certain embodiments, the panel 120 may be disposed between one of the first side 112 and the second side 114, the second side 114 and the third side 116, third side 116 and the fourth side 118, or the fourth side 118 and the first side 112, or along one or more of the first corner 113, the second corner 115, the third corner 117, or the fourth corner 119 of the flexible sheet 110. In the embodiment shown in FIG. 1A, the panel 120 may be disposed so as to abut the first corner 113. In further embodiments, such as that shown in FIG. 2A, the panel 120 may be disposed diagonally to the first corner 113 between the first side 112 and the second side 114. In the embodiment shown in FIGS. 3A-3C, the panel 120 may even be disposed along the entire surface area of the flexible sheet 110, that is, the panel 120 may span the length between the first side 112, the second side 114, the third side 116, and the fourth side 118.

The panel 120 may be configured to receive an electronic device 140. In this manner, the panel 120 may define a cavity 130. The electronic device 140 may comprise a mobile electronic device, such as a smartphone. The electronic device 140 may also comprise a tablet computer, a laptop computer, or virtually any other electronic device. Thus, the cavity 130 may be generally sized to receive any electronic device or more particularly, to receive the electronic device 140, such as the electronic device 140 shown in the FIGS.

The panel 120 may at least partially obscure a signal from the electronic device 140. According to certain embodiments, the panel 120 may be configured to obscure the signal from the electronic device 140 until a predetermined condition is met. In some instances, the predetermined condition may be a specified time period. In other embodiments, the predetermined condition may relate to a geographic location. In still further embodiments, the predetermined condition may comprise both a time period and a geographic location. As an example, the predetermined condition may be a live performance or other event and thus, the panel 120 may obscure the signal from the electronic device 140 while the user is located within the performance venue or during the duration of the performance. As a further example, the predetermined condition may be the user driving or the user having a private conversation. A person of ordinary skill in the art will recognize the predetermined condition may be virtually any scenario where it is desirable or convenient for the electronic device 140 to be rendered inaccessible.

With reference now to FIGS. 3A-3C, the panel 120 may further comprise a locking means 125. The locking means 125 may secure the cavity 130 and therefore, the electronic device 140. In this manner, the locking means 125 may render the electronic device 140 inaccessible to the user. In the embodiment shown in FIGS. 3A-3C, the locking means 125 may comprise a foldable flap 127, which may be sized to thread through a band 129. In certain embodiments, the locking means 125 may render the electronic device 140 inaccessible until the predetermined condition is met.

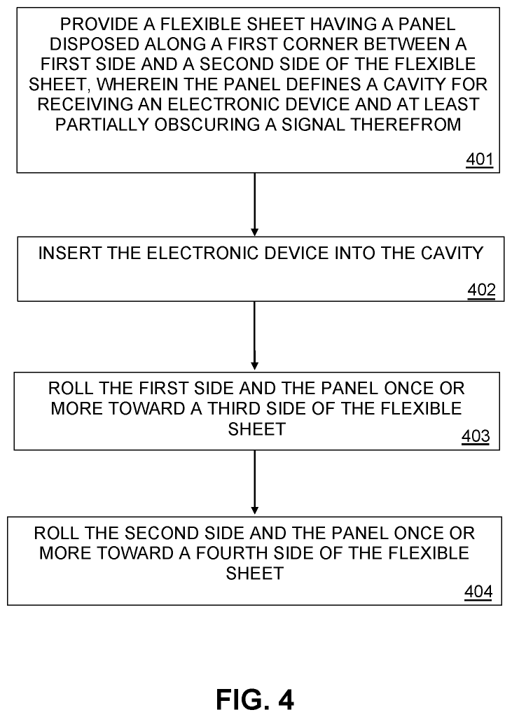

In one embodiment, as shown in FIGS. 1A-1D and 4, the panel 120 may be foldable within the flexible sheet 110 so as to form a square fold. In such embodiments, the wearable signal blocking method may comprise the steps of: providing a flexible sheet having a panel disposed along a first corner between a first side and a second side of the flexible sheet, wherein the panel defines a cavity for receiving an electronic device and at least partially obscuring a signal therefrom (block 401); inserting the electronic device into the cavity (block 402); rolling the first side and the panel once or more toward a third side of the flexible sheet (block 403); and rolling the second side and the panel once or more toward a fourth side of the flexible sheet (block 404).

In particular, as shown in FIG. 1A, the panel 120 may be disposed along the first corner 113 between the first side 112 and the second side 114 of the flexible sheet 110. As shown in FIG. 1B, after the electronic device 140 (obscured in the FIGS. 1A-1D) may be inserted into the cavity 130 (obscured in FIGS. 1B-1D), the panel 120 (obscured in FIGS. 1B-1D) and the first side 112 may then be rolled once or more toward the third side 116 of the flexible sheet 110. Next, as shown in FIGS. 1C-1D, the panel 120 and the second side 114 may then be rolled once or more toward the fourth side 118 of the flexible sheet 110.

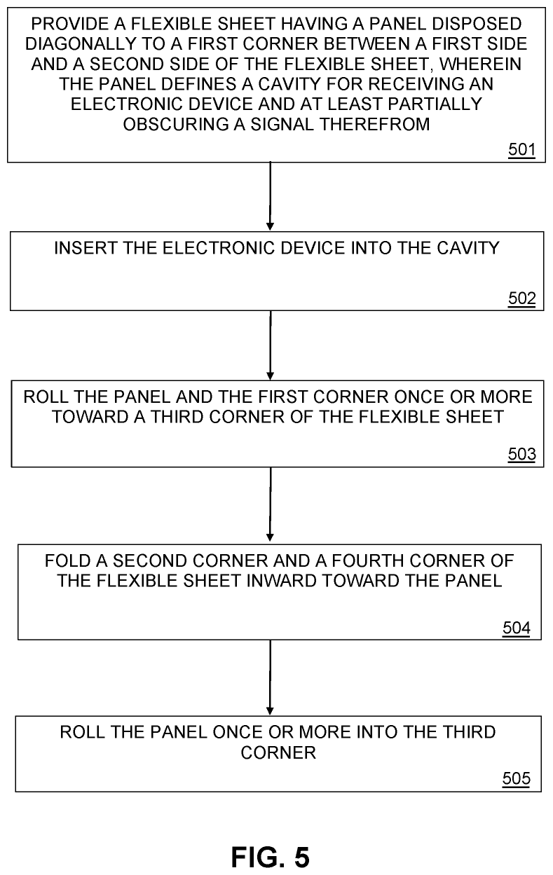

According to another embodiment of the wearable signal blocking method, shown in FIGS. 2A-2D and 5, the panel 120 may be foldable within the flexible sheet 110 so as to form a burrito fold. In these embodiments, the method may comprise the steps of: providing a flexible sheet having a panel disposed diagonally to a first corner between a first side and a second side of the flexible sheet, wherein the panel defines a cavity for receiving an electronic device and at least partially obscuring a signal therefrom (block 501); inserting the electronic device into the cavity (block 502); rolling the panel and the first corner once or more toward a third corner of the flexible sheet (block 503); folding a second corner and a fourth corner of the flexible sheet inward toward the panel (block 504); and rolling the panel once or more into the third corner (block 505).

As shown in FIG. 2A, the panel 120 may be disposed diagonally to the first corner 113 between the first side 112 and the second side 114 of the flexible sheet 110. First, the electronic device 140 (obscured in FIGS. 2A-2D) may be inserted into the cavity 130. In such embodiments, as shown in FIG. 2B, the panel 120 (obscured in FIGS. 2B-2D) and the first corner 113 (obscured in FIGS. 2B-2D) may then be rolled once or more toward the third corner 117 of the flexible sheet 110. As demonstrated in FIG. 2C, the second corner 115 (obscured in FIGS. 2C-2D) and the fourth corner 119 (obscured in FIGS. 2C-2D) may then be folded inward toward the panel 120. Lastly, the panel 120 may be rolled once or more into the third corner 117, as shown in FIG. 2D.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

### CONCLUSIONS, RAMIFICATIONS, AND SCOPE

While certain embodiments of the invention have been illustrated and described, various modifications are contemplated and can be made without departing from the spirit and scope of the invention. For example, while the illustrated embodiments show the panel disposed along one or more corners of the flexible sheet, the panel may be disposed virtually anywhere along the flexible sheet. Accordingly, it is intended that the invention not be limited, except as by the appended claims.

The teachings disclosed herein may be applied to other systems, and may not necessarily be limited to any described herein. The elements and acts of the various embodiments described above can be combined to provide further embodiments. All of the above patents and applications and other references, including any that may be listed in accompanying filing papers, are incorporated herein by reference. Aspects of the invention can be modified, if necessary, to employ the systems, functions and concepts of the various references described above to provide yet further embodiments of the invention.

Particular terminology used when describing certain features or aspects of the invention should not be taken to imply that the terminology is being refined herein to be restricted to any specific characteristics, features, or aspects of the wearable signal blocking device and method with which that terminology is associated. In general, the terms used in the following claims should not be constructed to limit the wearable signal blocking device and method to the specific embodiments disclosed in the specification unless the above description section explicitly define such terms. Accordingly, the actual scope encompasses not only the disclosed embodiments, but also all equivalent ways of practicing or implementing the disclosed system, method and apparatus. The above description of embodiments of the wearable signal blocking device and method is not intended to be exhaustive or limited to the precise form disclosed above or to a particular field of usage.

While specific embodiments of, and examples for, the method, system, and apparatus are described above for illustrative purposes, various equivalent modifications are possible for which those skilled in the relevant art will recognize.

While certain aspects of the method and system disclosed are presented below in particular claim forms, various aspects of the method, system, and apparatus are contemplated in any number of claim forms. Thus, the inventor reserves the right to add additional claims after filing the application to pursue such additional claim forms for other aspects of the wearable signal blocking device and method.

What is claimed is:

1. A wearable signal blocking device, comprising:
a flexible sheet configured to be worn by a user and having a first side, a second side, a third side, a fourth side, a first corner disposed between the first side and the second side, a second corner disposed between the second side and the third side, a third corner disposed between the third side and the fourth side, and a fourth corner disposed between the fourth side and the first side; and
a panel defining a cavity for receiving an electronic device and at least partially obscuring a signal therefrom.

2. The wearable signal blocking device of claim 1, wherein the panel is disposed along one of the first corner, the second corner, the third corner, or the fourth corner.

3. The wearable signal blocking device of claim 2, wherein the panel is foldable within the flexible sheet so as to form a square fold.

4. The wearable signal blocking device of claim 1, wherein the panel is disposed diagonally to the first corner, the second corner, the third corner, or the fourth corner.

5. The wearable signal blocking device of claim 4, wherein the panel is foldable within the flexible sheet so as to form a burrito fold.

6. The wearable signal blocking device of claim 1, wherein the panel further comprises a locking means for at least partially securing the cavity and rendering the electronic device inaccessible to the user.

7. The wearable signal blocking device of claim 6, wherein the locking means comprises a foldable flap and a band.

8. The wearable signal blocking device of claim 6, wherein the electronic device is inaccessible to the user until a predetermined condition is met.

9. The wearable signal blocking device of claim 8, wherein the predetermined condition is a geographic location.

10. The wearable signal blocking device of claim 8, wherein the predetermined condition is a time period.

11. A wearable signal blocking method, comprising the steps of:
providing a flexible sheet having a panel disposed diagonally to a first corner between a first side and a second side of the flexible sheet, wherein the panel defines a cavity for receiving an electronic device and at least partially obscuring a signal therefrom;
inserting the electronic device into the cavity;
rolling the panel and the first corner once or more toward a third corner of the flexible sheet;
folding a second corner and a fourth corner of the flexible sheet inward toward the panel; and
rolling the panel once or more into the third corner.

12. A wearable signal blocking method, comprising the steps of:
providing a flexible sheet having a panel disposed along a first corner between a first side and a second side of the flexible sheet, wherein the panel defines a cavity for receiving an electronic device and at least partially obscuring a signal therefrom;
inserting the electronic device into the cavity;
rolling the first side and the panel once or more toward a third side of the flexible sheet; and
rolling the second side and the panel once or more toward a fourth side of the flexible sheet.
